(19) United States
(12) Patent Application Publication
(10) Pub. No.: US 2023/0106606 A1
(43) Pub. Date: Apr. 6, 2023

(54) APPARATUS, SYSTEM AND METHOD FOR PROVIDING A SEMICONDUCTOR WAFER LEVELING RIM

(71) Applicant: JABIL INC., St. Petersburg, FL (US)

(72) Inventor: JEROEN BOSBOOM, St. Petersburg, FL (US)

(73) Assignee: JABIL INC., St. Petersburg, FL (US)

(21) Appl. No.: 17/800,528

(22) PCT Filed: Feb. 17, 2020
(86) PCT No.: PCT/US20/18492

§ 371 Date: Aug. 17, 2022

(51) Int. Cl. H01L 21/687; H01L 21/683

(52) U.S. Cl. CPC H01L 21/68721; H01L 21/6838

(57) ABSTRACT

An apparatus, system and method for a wafer leveling rim, and for installing a wafer leveling rim. The leveling rim for a semiconductor wafer may include: a thin, substantially rigid receiver ring suitable to receive a circumferential rim of the semiconductor wafer; and a substantially flexible containment ring removably associated with the rigid receiver ring. Thereby, the rigid receiver ring imparts rigidity to a circumferential shape of the semiconductor wafer, and the containment ring retains the semiconductor wafer within the rigid receiver ring.

### CROSS-REFERENCE TO RELATED APPLICATION

This application claims the benefit of priority to International Application No. PCT/US2020/018492, filed Feb. 17, 2020; entitled APPARATUS, SYSTEM AND METHOD FOR PROVIDING A SEMICONDUCTOR WAFER LEVELING RIM, the entirety of which is incorporated herein by reference as if set forth in its entirety.

### BACKGROUND

### Field of the Disclosure

The present disclosure relates to the transfer and processing of articles, such as semiconductor wafers, and more particularly to an apparatus, system and method for providing a semiconductor wafer leveling rim.

### Description of the Background

The use of robotics is well established as a manufacturing expedient, particularly in applications where human handling is inefficient and/or undesirable. One such circumstance is in the semiconductor arts, in which robotics and automated stations are used to handle and hold wafers during various process steps. Such process steps may include, by way of example, chemical mechanical planarization (CMP), etching, deposition, passivation, and various other processes in which a sealed and/or “clean” environment must be maintained, such as to limit the likelihood of contamination and to ensure that various specific processing conditions are met.

Current practice in the semiconductor arts to robotically handle these wafers often includes the use of an end effector operably attached to the robotics, such as in order to load semiconductor wafers from a loading stack into the various processing ports that may correspond to the aforementioned exemplary process steps. The robotics are employed to deploy the end effector to retrieve the wafer from a particular port or stack, such as before and/or after processing in an associated process chamber, and/or to associate the wafer with a station, such as may include a station chuck onto which the wafer is placed.

The wafer may thus be shuttled by the robotics connectively associated with the end effector between stations for additional processing. When a given wafer process is complete, the robotics may move the processed wafer from its station and return the processed semiconductor wafer to a loading port. It is typical that a stack of several semiconductor wafers is processed in this manner during each process run.

The processed semiconductor wafers are often in the 0.05 to 0.10 mm thickness range. This extraordinary thinness not only makes the wafers difficult to handle, as the wafers may droop, sag or pucker based on the location of and gripping by handling devices, but even more so may cause the wafers to warp due to wafer processing and handling. That is, a thin wafer may be misshapen by warping or bending, in the manner of a potato chip, during semiconductor handling and processing. By way of example, this potato chip shape may exhibit an alternating pitch along the wafer rim, such as every 90° or so, radially along the wafer's circumferential rim.

The aforementioned wafer drooping, bending and warping may generally make the wafer unsuitable for additional processing. This unsuitability is, in part, due to the design of conventional semiconductor automation processing tools and equipment to process flat, rigid semiconductor wafers. By way of example, wafer stack trays may lack sufficient drawer height to accommodate a warped wafer, and end effectors designed to suction to or otherwise grasp flat wafers may be unsuitable to retain warped wafers. That is, in the event a wafer is bowed or warped, the wafer will likely not fit into a wafer cassette of multiple wafers for processing.

The known art addresses such wafer-shape flaws principally by bonding of another substrate to an in-process wafer, such that the in-process wafer retains the shape of the bonded substrate, thereby avoiding drooping or warping. However, the bonded substrates in the known art lead to issues in processing semiconductor wafers. For example, the temporary bonding to the wafers of these other substrates, such as glass substrates, necessitates a later detachment of the other substrate. Such detachment may be performed, for example, by a laser ablation of a glue bond. However, this detachment adds additional process steps, thereby making the subject semiconductor process less efficient, and may also provide highly undesirable targeted heating to certain areas of and in-process wafer. Laser ablation detachment may also significantly increase the expense of semiconductor processing due to the use of expensive lasers.

Moreover, the removal of the other substrate may leave behind residue that may adversely affect the subsequent semiconductor processes, or may cause residual static that may damage components on a wafer. Yet further, the bonding of another substrate may preclude the occurrence of processes on the side of the wafer to which the other substrate is bonded.

Therefore, the need exists for an apparatus, system, and method of preventing warping and drooping of and in-process, semiconductor wafer, without the use of a sacrificial secondary substrate.

### SUMMARY

Certain embodiments are and include an apparatus, system and method for a wafer leveling rim, and for installing a wafer leveling rim. The leveling rim for a semiconductor wafer may include: a thin, substantially rigid receiver ring suitable to receive a circumferential rim of the semiconductor wafer; and a substantially flexible containment ring removably associated with the rigid receiver ring. Thereby, the rigid receiver ring imparts rigidity to a circumferential shape of the semiconductor wafer, and the containment ring retains the semiconductor wafer within the rigid receiver ring.

The rigid receiver ring may comprise a plurality of mating features suitable to provide the removable association. The mating features may comprise a plurality of radial slots, such as 60 degrees radially about the circumference of the wafer.

The containment ring may comprise a plurality of retaining features suitable to provide the removable association. The retaining features may comprise a plurality of radial tabs.

An automated attachment system and method for attaching a leveling rim having a retainer ring and a containment rim to a semiconductor wafer may include: a chuck capable of receiving thereon a semiconductor wafer; a plurality of ring guides to positionally maintain the retainer ring about the chuck as the wafer is seated in the retainer ring; a downward aligner suitable to align and drop the containment ring into removable association with the retainer ring, enclosing the wafer circumferential therebetween.

### BRIEF DESCRIPTION OF THE DRAWINGS

The exemplary compositions, systems, and methods shall be described hereinafter with reference to the attached drawings, which are given as non-limiting examples only, in which:

FIG. 1 is an illustration of a wafer handling system;

FIG. 2 is an illustration of a wafer upon an end effector;

FIG. 3 illustrates a leveling rim;

FIG. 4 is an illustration of a leveling rim;

FIG. 5 is an illustration of a leveling rim;

FIG. 6 is an illustration of a leveling rim;

FIG. 7 is an illustration of a leveling rim attachment system;

FIG. 8 are illustrations of aspects of a leveling rim attachment system;

FIG. 9 are illustrations of aspects of a leveling rim attachment system; and

FIG. 10 are illustrations of aspects of a leveling rim attachment system.

### DETAILED DESCRIPTION

The figures and descriptions provided herein may have been simplified to illustrate aspects that are relevant for a clear understanding of the herein described apparatuses, systems, and methods, while eliminating, for the purpose of clarity, other aspects that may be found in typical similar devices, systems, and methods. Those of ordinary skill may thus recognize that other elements and/or operations may be desirable and/or necessary to implement the devices, systems, and methods described herein. But because such elements and operations are known in the art, and because they do not facilitate a better understanding of the present disclosure, for the sake of brevity a discussion of such elements and operations may not be provided herein. However, the present disclosure is deemed to nevertheless include all such elements, variations, and modifications to the described aspects that would be known to those of ordinary skill in the art.

Embodiments are provided throughout so that this disclosure is sufficiently thorough and fully conveys the scope of the disclosed embodiments to those who are skilled in the art. Numerous specific details are set forth, such as examples of specific components, devices, and methods, to provide a thorough understanding of embodiments of the present disclosure. Nevertheless, it will be apparent to those skilled in the art that certain specific disclosed details need not be employed, and that embodiments may be embodied in different forms. As such, the disclosed embodiments should not be construed to limit the scope of the disclosure. As referenced above, in some embodiments, well-known processes, well-known device structures, and well-known technologies may not be described in detail.

The terminology used herein is for the purpose of describing particular embodiments only and is not intended to be limiting. For example, as used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The steps, processes, and operations described herein are not to be construed as necessarily requiring their respective performance in the particular order discussed or illustrated, unless specifically identified as a preferred or required order of performance. It is also to be understood that additional or alternative steps may be employed, in place of or in conjunction with the disclosed aspects.

When an element or layer is referred to as being “on”, “upon”, “connected to” or “coupled to” another element or layer, it may be directly on, upon, connected or coupled to the other element or layer, or intervening elements or layers may be present, unless clearly indicated otherwise. In contrast, when an element or layer is referred to as being “directly on,” “directly upon”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). Further, as used herein the term “and/or” includes any and all combinations of one or more of the associated listed items.

Yet further, although the terms first, second, third, etc. may be used herein to describe various elements, components, regions, layers and/or sections, these elements, components, regions, layers and/or sections should not be limited by these terms. These terms may be only used to distinguish one element, component, region, layer or section from another element, component, region, layer or section. Thus, terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the embodiments.

The embodiments may provide a wafer leveling rim. The provided wafer leveling rim may comprise a thin, substantially rigid receiver ring to be placed about the circumferential rim of a subject wafer in conjunction with a less rigid containment ring connective with the receiver ring. That is, the receiver ring and the containment ring may each have respective features that allow the two rings to be conjoined relatively securely about a wafer's circumferential rim, thereby retaining the wafer within conjoined rings of the leveling rim.

Accordingly, the disclosed leveling rim and system may substantially enhance the rigidity of the circumferential rim of the wafer about which the leveling rim is placed. This enhanced rigidity of shape may better maintain the shape of the wafer during semiconductor processes and handling. That is, the leveling rim may at least substantially preclude drooping of the wafer during wafer handling, such as handling by an end effector, and may better maintain the flatness of the wafer by maintaining the circumference of the wafer. This functionality may thus prevent warping of the wafer during semiconductor processes, and may enhance the suitability of the wafer for placement into wafer trays and process chambers, by way of nonlimiting example. Moreover, the placement of the leveling rim only about the circumferential rim of the subject wafer may allow for processing on both sides of the wafer, and may do so without the process blocking, glue residue, ablation equipment, or other drawbacks of the known art.

The disclosed wafer leveling rim is generally easy to assemble, such as either in a manual or an automated process whereby the aforementioned containment ring and receiver rings are assembled, to thereby protect each in-process wafer. Thus, the number of wafers which can be stacked is increased in the embodiments; wafer scanning and alignment during processing is improved in the embodiments with negligible warpage; and wafer processing efficiencies are thus substantially enhanced in the embodiments. By way of nonlimiting example, a substantial warpage, such as a 20 mm wafer warpage, may be very substantially reduced through the use of the embodiments, such as to 1 to 2 mm, by way of nonlimiting example.

The disclosed leveling rim may be suitable for process retrofitting, at least in that it may require no special processing for each wafer subjected thereto. The attachment of the leveling ring, and the detaching thereof, may require modest fixturing, as will be understood to the skilled artisan in light of the discussion herein. As such, the leveling rim disclosed may be applied to each in-process wafer before the wafer enters into a processing system, and may be detached from each respective wafer upon exit of said wafer from that wafer processing system.

More particularly, a rigid but substantially thin receiver ring may provide mating features to the retaining features on the substantially less rigid containment ring. Physical association of the mating features with the retaining features may effectively “clip” the containment ring into the receiver ring about the circumference of a retained wafer.

By way of example, the mating features may comprise radial slots, such as roughly every 60° radially about the leveling ring. The corresponding retaining features may comprise small radial tabs on the containment ring at substantially the same intervals as the aforementioned radial slots on the receiver ring. This allows insertion of the radial tabs into the radial slots to effectuate an engagement of the container ring over an enclosed wafer rim and into the receiver ring.

In embodiments, the receiver ring may provide rigidity to enable self-supporting of the leveling rim, and the joinder of the mating features with the retaining features may provide sufficient flexure so as to act as radial springs sections, These radial springs may account for stresses on certain radial portions of the wafer during handling and processing, wherein such stresses may be dissipated by the effective springs without sufficiently stressing the contained wafer in a manner that might cause drooping or warpage.

In accordance with the discussion above, the leveling rim may effectively provide a circumferential “frame” to maintain the circumferential shape and flatness of an enclosed wafer. Further, the design discussed throughout may cause alternating warping forces on the wafer to cancel one another, such as at approximately every 90° radially about the wafer, thereby dissipating such forces in a manner that avoids wafer warpage as discussed above.

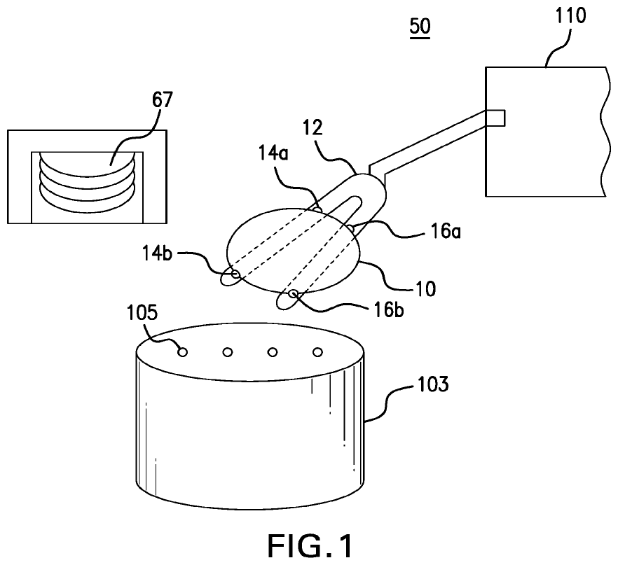

FIG. 1 illustrates an automated handling system 50 suitable to precisely handle semiconductor wafers of varying diameters, compositions and physical attributes. The handling system 50 may be capable of handling the substrates, such as wafer 10, in a rapid, ordered succession for processing. The substrates 10 supplied may be manipulated or transferred upon end effector 12 among and between stacks 67 and various stationary points 103 for processing, in part, by robotics, such as may be provided in base 110, to perform the aforementioned manipulation and transfer. The stationary points 103 may comprise one or more chucks, such as may grip the substrates 10 upon placement onto the chuck 103. This gripping may be performed, by way of example, through the use of one or more vacuums 105.

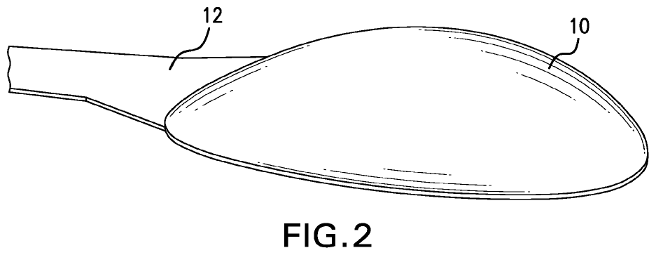

FIG. 2 illustrates a substantially bowed wafer 10 upon an end effector 12 in a typical semiconductor process. Of note, the illustrated wafer 10 would be unsuitable for processing, as it would be infeasible for the wafer to fit within the stack or a wafer cassette 67 of FIG. 1, or to be gripped by vacuum 105.

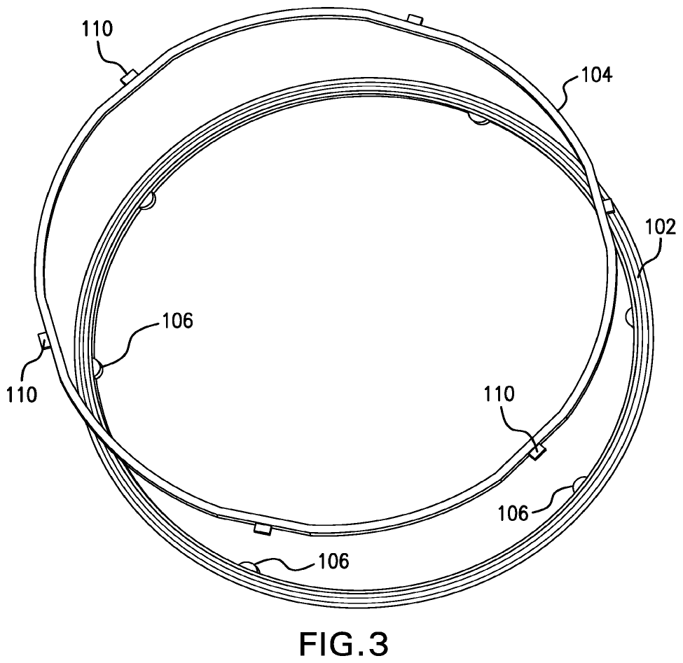

FIG. 3 illustrates a substantially rigid retainer ring 102, and a less rigid containment ring 104 for physical engagement with the retainer ring 102. Also evident in FIG. 3 are a plurality of mating features 106 on the retainer ring 102. The mating features 106 are shown as receiving slots, by way of nonlimiting example.

A plurality of retaining features 110 are additionally shown on the containment ring 104. The retaining features 110 are illustratively shown in FIG. 3 as insertion tabs, by way of nonlimiting example, although it will be appreciated that other feature types suitable to mate with mating features 106 may also be provided in accordance with this disclosure.

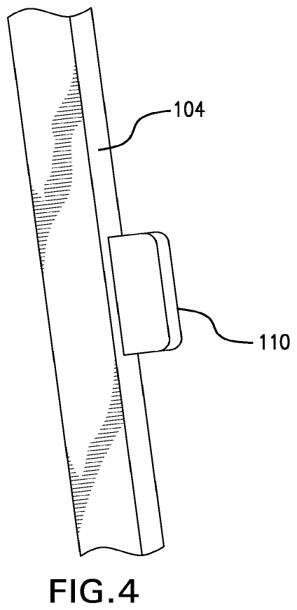

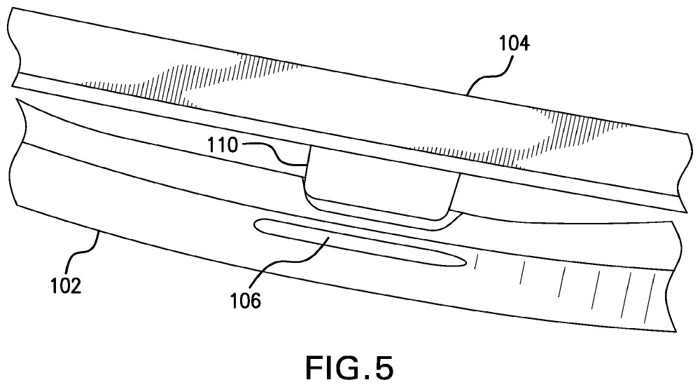

FIG. 4 shows with particularity an exemplary embodiment in which the retaining features 110 comprise tabs. FIG. 5 illustrates an exemplary embodiment in which each radial tab 110 on the containment ring 104 is inserted into a corresponding receiving slot 106 on the retainer ring 102 so as to contain therebetween the circumferential outer rim of the subject wafer 10 (not shown in FIG. 5) between the two rings 102, 104.

Of note, and as illustrated herein by way of example, the mating feature 106 and retaining feature 110 pairings may, in certain embodiments, be placed at roughly every 60° radially about each of the respective rings 102, 104. Of course, other dispositions of the pairings may also be employed, such as every 45° or every 90°.

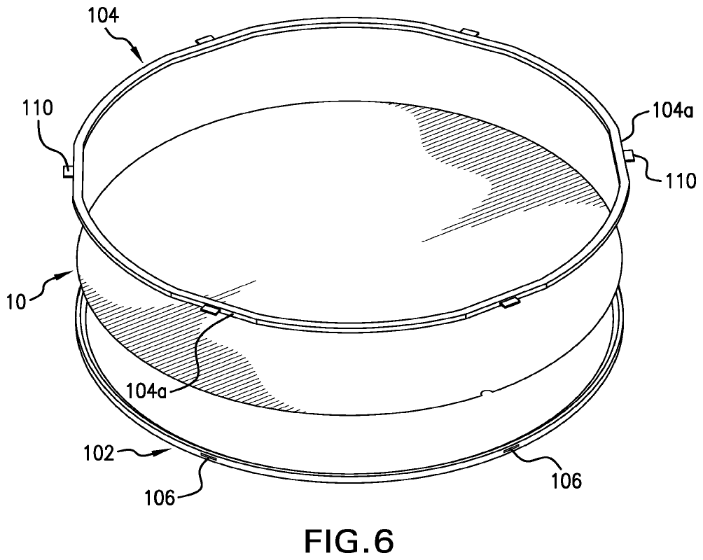

FIG. 6 provides an illustration of the association of a less rigid containment ring 104 and a more rigid retainer ring 102 using the exemplary tab 110 and slot 106 paired features discussed above. Also illustrated in FIG. 6 is the containment of the wafer 10 between the two aforementioned rings.

The illustration additionally shows that the retainer ring 102 may be only somewhat round in shape, to correspond to the round shape of a retained wafer 10. The containment ring 104 may additionally include substantially flat portions 104a along the inner circumference thereof. These straight relief aspects, such as may be proximate to the tabs 110 on the containment ring 104, may provide a gap suitable to allow for alignment and/or scanning of the wafer 10.

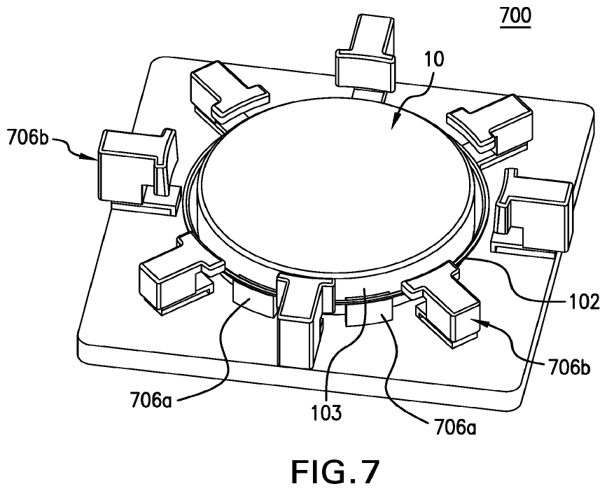

FIG. 7 illustrates an exemplary automated attachment system 700 for placement of a subject wafer 10 into the disclosed leveling rim. As shown, a chuck 103, such as a vacuum chuck 103, may be provided at the center of the rim attachment system 700, such as to retain and/or draw vacuum on a wafer 10 placed upon the chuck 103. Also illustrated are a plurality of supports and guides 706 suitable to support the weight of and positionally maintain a retainer ring. Of note, the retainer ring guides 706a may open and close with a pressure suitable to position and release a retainer ring 102 while avoiding damage to the physical integrity thereof. Also illustrated in FIG. 7 are a plurality of wafer guides 706b, which also may open and close with predetermined pressures, as indicated above, so as to avoid damage to a subject wafer 10, wherein the wafer guides 706b position only guide the wafer 10 into the retaining ring 102.

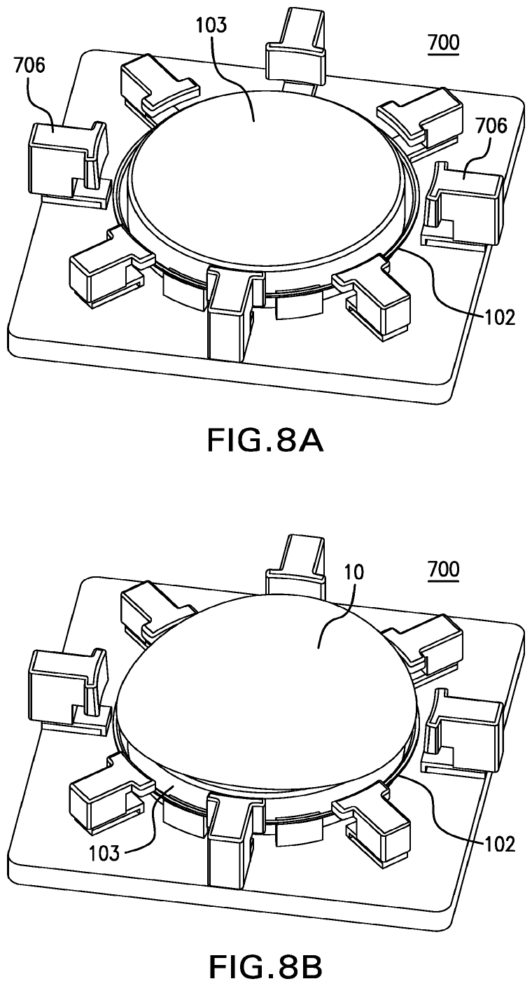

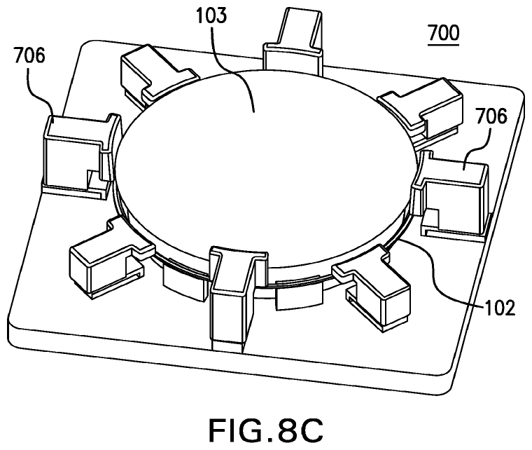

FIGS. 8A, B, and C illustrate the association of a retainer ring 102 with the rim attachment system 700, and a subsequent placement of a wafer 10 into the retaining ring 102. More particularly, FIG. 8A, illustrates the opening of the guides 706 referenced above, and the placement of the retainer ring 102 around the wafer chuck 103. FIG. 8B illustrates the placement of the wafer 10 onto the wafer chuck 103. Thereafter, FIG. 8C illustrates the application of a light force to seat the wafer 10, such as to seat the wafer 10 within the retainer ring 102, and to accordingly close the guides 706 to accomplish this seating. Other suitable methodologies may be employed during FIGS. 8A, B, and C, such as the use of LED sighting and similar wafer alignment technologies, to ensure proper placement of the retaining ring 102 and seating of the wafer 10 therein.

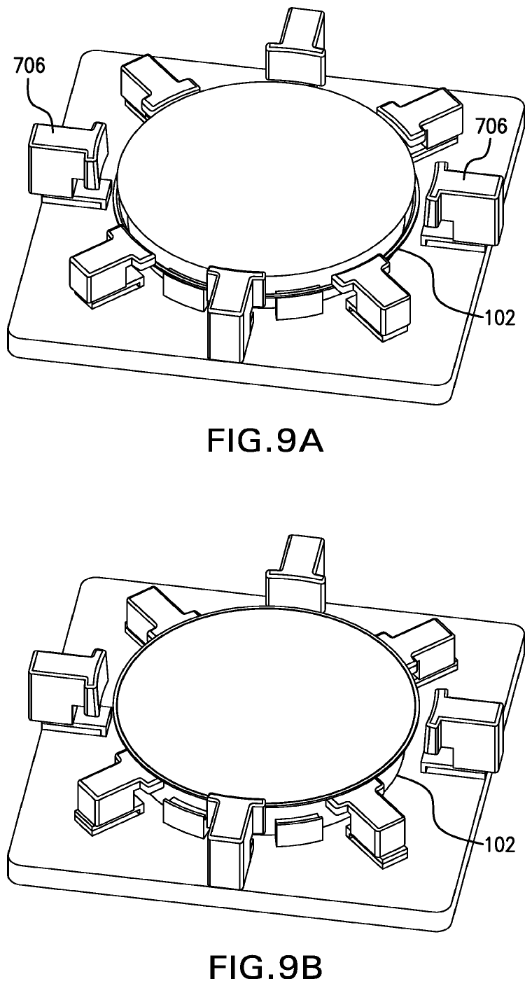

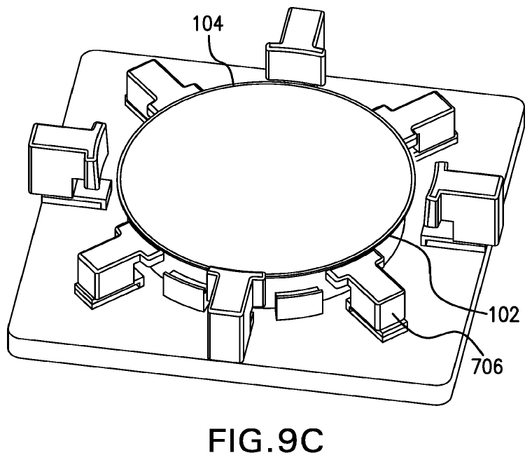

FIGS. 9A, B, and C illustrate the association of the containment ring 104 with the wafer 10 placed upon the chuck 103 in FIGS. 8A, B and C. More particularly, FIG. 9A illustrates the opening of the guides 706 to allow for the manual or automated positioning and downward placement of the containment ring 104. FIG. 9B illustrates the lifting and positioning of the retainer ring 102 such that the containment ring 104 coming from above the retainer ring 102 may be subjected to alignment of the mating features 106 and the retaining features 110 discussed throughout. FIG. 9C illustrates the physical association and seating of the retainer ring 102 and containment ring 104, such as by extending the support guides 706 below the wafer 10 and the retainer ring 102 upwards while maintaining the shape and tab location of the containment ring 104 moving downwards.

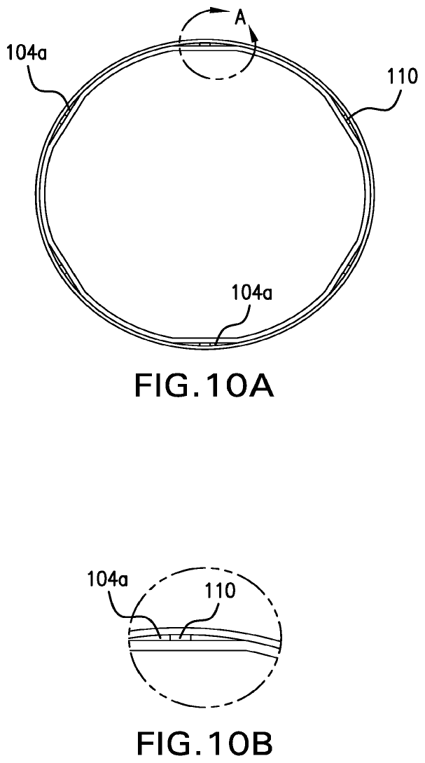

FIGS. 10A and B illustrates the inclusion of the aforementioned alignment gaps 104a to allow for an alignment or to detect the position of the wafer 10 in the disclosed embodiments. More specifically, FIG. 10A illustrates the presence of at least partially straight aspects 104a along multiple radial portions of the container ring 104. These straight edge aspects 104a may effectuate gaps, or notches, in one or two dimensions, as is illustrated in FIGS. 10A and B. These notches allow for detection of the wafer position within the leveling rim by an aligner.

The foregoing apparatuses, systems and methods may also include the control of the various robotic and vacuum functionality referenced throughout. Such control may include, by way of non-limiting example, manual control using one or more user interfaces, such as a controller, a keyboard, a mouse, a touch screen, or the like, to allow a user to input instructions for execution by software code associated with the robotics and with the systems discussed herein. Additionally, and as is well known to those skilled in the art, system control may also be fully automated, such as wherein manual user interaction only occurs to “set up” and program the referenced functionality, i.e., a user may only initially program or upload computing code to carry out the predetermined movements and operational sequences discussed throughout. In either a manual or automated embodiment, or in any combination thereof, the control may be programmed, for example, to relate the known positions of substrates, the robotics, the stationary points, and the relative positions there between, for example.

It will be appreciated that the herein described systems and methods may operate pursuant to and/or be controlled by any computing environment, and thus the computing environment employed not limit the implementation of the herein described systems and methods to computing environments having differing components and configurations. That is, the concepts described herein may be implemented in any of various computing environments using any of various components and configurations.

Further, the descriptions of the disclosure are provided to enable any person skilled in the art to make or use the disclosed embodiments. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but rather is to be accorded the widest scope consistent with the principles and novel features disclosed herein.

What is claimed is:

1. A leveling rim for a semiconductor wafer, comprising:
a thin, substantially rigid receiver ring suitable to receive a circumferential rim of the semiconductor wafer; and
a substantially flexible containment ring removably associated with the rigid receiver ring.

2. The leveling rim of claim 1, wherein the rigid receiver ring comprises a plurality of mating features suitable to provide the removable association.

3. The leveling rim of claim 2, wherein the mating features comprise a plurality of radial slots.

4. The leveling rim of claim 3, wherein the radial slots are approximately every 60 degrees radially about the circumference of the semiconductor wafer.

5. The leveling rim of claim 1, wherein the containment ring comprises a plurality of retaining features suitable to provide the removable association.

6. The leveling rim of claim 5, wherein the retaining features comprise a plurality of radial tabs.

7. The leveling rim of claim 6, wherein the radial tabs are approximately every 60 degrees radially about the circumference of the semiconductor wafer.

8. The leveling rim of claim 1, wherein the rigid receiver ring imparts rigidity to a circumferential shape of the semiconductor wafer, and wherein the containment ring retains the semiconductor wafer within the rigid receiver ring.

9. The leveling rim of claim 8, wherein the rigidity of the circumferential shape minimizes warping of the semiconductor wafer.

10. The leveling rim of claim 9, wherein the warping is in a range of 1 mm to 2 mm.

11. The leveling rim of claim 1, wherein the removable association comprises radial spring connections.

12. The leveling rim of claim 1, wherein the containment ring is absent from processing areas of the semiconductor wafer.

13. The leveling rim of claim 1, wherein the semiconductor wafer has a thickness in a range of 0.05 mm to 0.10 mm.

14. The leveling rim of claim 1, wherein the retainer ring comprise a series of flat relief portions about a circumference thereof.

15. The leveling rim of claim 14, wherein the series of flat relief portions provides for alignment measurements.

16. An automated attachment system for attaching a leveling rim having a retainer ring and a containment rim to a semiconductor wafer, comprising:
a chuck capable of receiving thereon a semiconductor wafer;
a plurality of ring guides to positionally maintain the retainer ring about the chuck as the wafer is seated in the retainer ring;
a downward aligner suitable to align and drop the containment ring into removable association with the retainer ring, enclosing the wafer circumferential therebetween.

17. The system of claim 16, wherein the chuck is a vacuum chuck.

18. The system of claim 16, wherein the plurality of ring guides are pressurized.

19. The system of claim 16, wherein the wafer alignment to the retainer ring is subject to LED sighting.

20. The system of claim 16, wherein the removable association comprises an insertion of tabs into slots.
